(19) United States
(12) Patent Application Publication
(10) Pub. No.: US 2009/0166063 A1
(43) Pub. Date: Jul. 2, 2009

(54) STIFFENER AND STRENGTHENED FLEXIBLE PRINTED CIRCUIT BOARD HAVING THE SAME

(75) Inventors: YUNG-WEI LAI, Tayuan (TW); CHENG-WEI KUO, Tayuan (TW); SHING-TZA LIOU, Tayuan (TW)

Correspondence Address: PCE INDUSTRY, INC.;ATT. Steven Reiss, 458 E. LAMBERT ROAD, FULLERTON, CA, 92835, US

(73) Assignee: FOXCONN ADVANCED TECHNOLOGY INC., Tayuan (TW)

(21) Appl. No.: 12/144,254

(22) Filed: Jun. 23, 2008

(30) Foreign Application Priority Data
Dec. 28, 2007 (CN) 2007 10203503.9

(51) Int. Cl. H05K 1/03; B32B 27/08; C08G 73/10

(52) U.S. Cl. 174/254; 428/473.5; 428/336; 528/367

(57) ABSTRACT

An exemplary stiffener includes at least one polyimide layer and at least one polyetherimide layer adhered to the at least one polyimide layer. The at least one polyetherimide layer is represented by the following general formula:

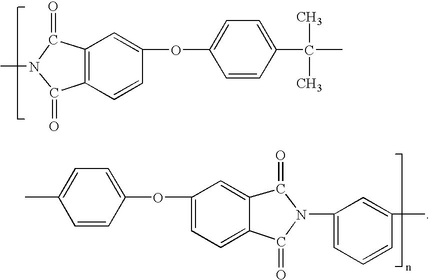

### CROSS-REFERENCE TO RELATED APPLICATIONS

This application is related to commonly-assigned co-pending applications (application Ser. No. 12/140,480) entitled, “STIFFENER AND STRENGTHENED FLEXIBLE PRINTED CIRCUIT BOARD HAVING THE SAME”, filed on the 17th of June 2008, and “STIFFENER SHEET AND FLEXIBLE PRINTED CIRCUIT BOARD USING THE SAME”, filed XXXX (Attorney. Docket No. US18595). Disclosures of the above identified applications are incorporated herein by reference.

### BACKGROUND

1. Technical Field

The present invention relates to flexible printed circuit boards, particularly to a stiffener and a strengthened flexible printed circuit board having the stiffener.

2. Description of Related Art

In recent years, electronic products have achieved miniaturization in volume and diversification in function. Flexible printed circuit boards (FPCBs) are widely used for electrical connection because of their flexibility and lightness.

Typically, a mass of electronic components are mounted onto a surface of a flexible printed circuit board to achieve various functions. For mounting and supporting the electronic components, a stiffener made of polyimide (PI) is usually attached onto the rear of the flexible printed circuit board via an adhesive layer made of epoxy resin to increase mechanical strength of the flexible printed circuit board, thereby obtaining a strengthened flexible printed circuit board. However, due to difference between coefficient of thermal expansion (CET) of the polyimide stiffener and that of the epoxy resin adhesive layer, the polyimide stiffener and the epoxy resin adhesive layer have different expansion sizes or shrinkage sizes under a heating condition. Thus, the strengthened flexible printed circuit board will become warped after attaching the polyimide stiffener onto the flexible printed circuit board via the epoxy resin adhesive layer, thereby increasing difficulties of surface mounting electronic components thereon.

What is needed, therefore, is a stiffener and a strengthened flexible printed circuit board with the same so as to increase mechanical strength of the flexible printed circuit board and avoid wrap of the strengthened flexible printed circuit board.

### SUMMARY

One present embodiment provides a stiffener. The stiffener includes at least one polyimide layer and at least one polyetherimide layer adhered to the at least one polyimide layer. The at least one polyetherimide layer is represented by the following general formula:

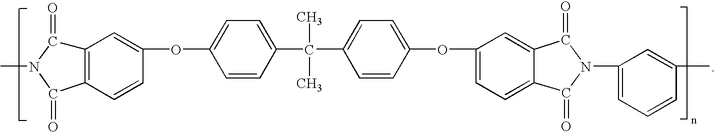

Another present embodiment provides a strengthened flexible printed circuit board. The strengthened flexible printed circuit board includes a flexible printed circuit board and a stiffener attached onto the flexible printed circuit board. The stiffener includes at least one polyimide layer and at least one polyetherimide layer adhered to the at least one polyimide layer. The at least one polyetherimide layer is represented by the following general formula:

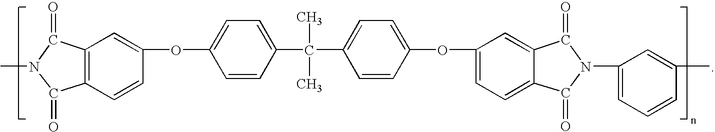

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, cross-sectional view of a stiffener according to a first embodiment.

FIG. 2 is a schematic, cross-sectional view of a stiffener according to a second embodiment.

FIG. 3 is a schematic, cross-sectional view of a stiffener according to a third embodiment.

FIG. 4 is a schematic, cross-sectional view of a strengthened flexible printed circuit board having the stiffener shown in FIG. 1.

FIG. 5 is a schematic, cross-sectional view of another strengthened flexible printed circuit board having the first stiffener shown in FIG. 1.

FIG. 6 is a schematic, cross-sectional view of a strengthened flexible printed circuit board having the first stiffener shown in FIG. 3.

### DETAILED DESCRIPTION OF THE EMBODIMENTS

Embodiments will now be described in detail below with reference to the drawings.

A stiffener includes at least one polyimide layer and at least one polyetherimide layer adhered to the at least one polyimide layer, thereby forming a multilayer structure. Each of the polyimide layers has a thickness in a range from 25 to 75 microns. Each of the polyetherimide layers has a thickness in a range from 25 to 75 microns. A total thickness of the stiffener is in a range from 25 to 250 microns. Thus, the stiffener has adequate rigidity to increase mechanical strength of a flexible printed circuit board and has adequate ductility to maintain flexibility of a strengthened flexible printed circuit board with the stiffener for a roll-to-roll process.

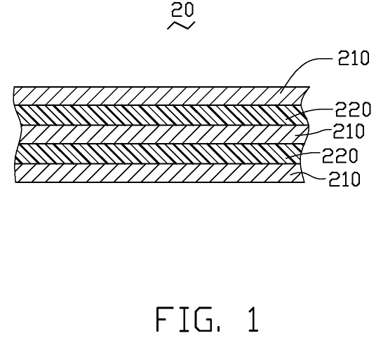

Referring to FIG. 1, a stiffener 20 according to a first embodiment is shown.

The stiffener 20 includes at least one polyimide layer 210 and at least one polyetherimide layer 220 arranged in an alternate fashion. The number of the polyimide layers 210 is one greater than that of the polyetherimide layers 220. Each of the polyetherimide layers 220 is disposed between two polyimide layers 210 adjacent thereto and is configured for adhering to the two polyimide layers 210. Thus, the stiffener 20 has two polyimide layers 210 on two opposite outer sides thereof, respectively. Each of the two polyimide layers 210 on two opposite outer sides of the stiffener 20 is configured for adhering to a flexible printed circuit board. In the present embodiment, the stiffener 20 includes three polyimide layers 210 and two polyetherimide layers 220 arranged in an alternate fashion.

The polyetherimide layer 220 is represented by the following general formula:

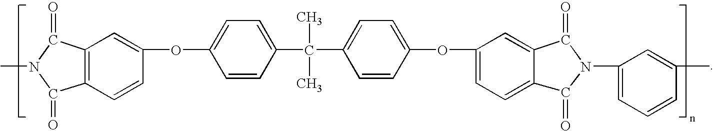

The polyetherimide can be prepared from one of 4,4′-diaminodiphenyl ether, 1,3-benzenediamine and 1,4-benzenediamine, and 2,2-bis[4-(3,4-dicarboxyphenoxy)phenyl] propane dianhydride by condensation polymerization in a N-methylacetamide solution. It is noted that the polyetherimide can be prepared using other practicable methods. The polyetherimide has a number of ether groups in the molecular structure thereof. The ether groups can increase flexibility of the molecular structure. Thus, the polyetherimide layer 220 comprised of the polyetherimide has good flexibility. In addition, the polyetherimide is flowable and has a good adhesive property in a melt status. Therefore, the polyetherimide layer 220 can be configured for adhering to the polyimide layers 210 or other components such as a flexible printed circuit board. Moreover, coefficient of thermal expansion for the polyetherimide is in a range from 16×10⁻⁶ to 18×10⁻⁶ K⁻¹. In general, coefficient of thermal expansion for the polyimide is in a range from 18×10⁻⁶ to 28×10⁻⁶ K⁻¹. Therefore, the polyetherimide has similar thermal expansion property to the polyimide. The polyimide layers 210 and the polyetherimide layers 220 have substantially consistent expansion sizes or shrinkage sizes under a heating condition. Thus, the stiffener 20 will not become warped when the stiffener 20 is attached onto a flexible printed circuit board by a thermal press process.

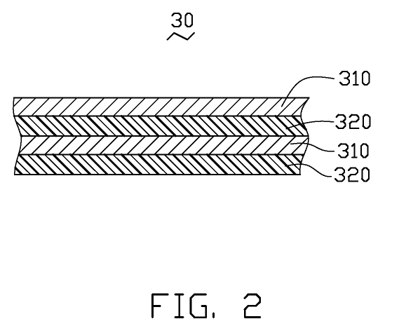

Referring to FIG. 2, a stiffener 30 according to a second embodiment is shown. The stiffener 30 also includes a number of polyimide layers 310 and a number of polyetherimide layers 320 arranged in an alternate fashion. The number of the polyimide layers 310 is equal to that of the polyetherimide layers 320. Thus, the stiffener 30 has one polyimide layer 310 and one polyetherimide layer 320 on two opposite outer sides thereof, respectively. The one polyimide layer 310 and the one polyetherimide layer 320 on two opposite outer sides of the stiffener 30 are configured for adhering to a flexible printed circuit board. In the present embodiment, the stiffener 30 includes two polyimide layers 310 and two polyetherimide layers 320 arranged in an alternate fashion. It is noted that the stiffener 30 can includes a polyimide layers 310 and a polyetherimide layers 320 adhering to each other.

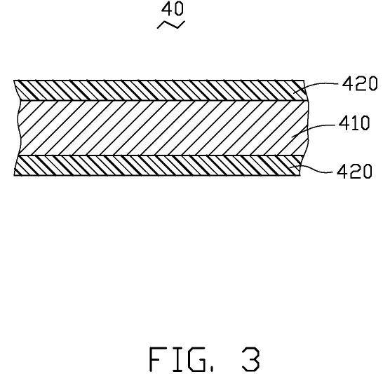

Referring to FIG. 3, a stiffener 40 according to a third embodiment is shown. The stiffener 40 includes a number of polyimide layers 410 and a number of polyetherimide layer 420 arranged in an alternate fashion. The number of the polyimide layers 410 is one less than that of the polyetherimide layers 420. Thus, the stiffener 40 has two polyetherimide layers 420 on two opposite outer sides thereof, respectively. The polyetherimide layers 420 on two opposite outer sides of the stiffener 40 are configured for adhering to a flexible printed circuit board. In the present embodiment, the stiffener 40 includes two polyetherimide layers 420 and a polyimide layer 410 between the two polyetherimide layers 320.

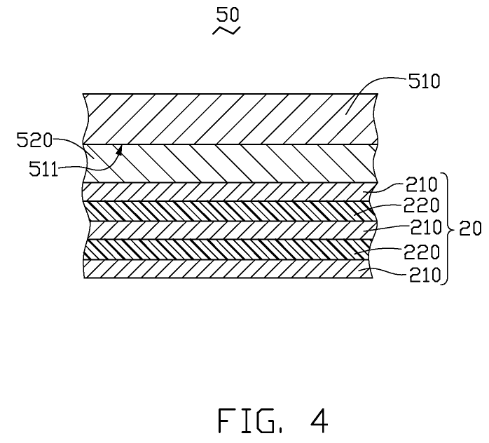

Referring to FIG. 4, a strengthened flexible printed circuit board 50 having the stiffener 20 is shown. The strengthened flexible printed circuit board 50 includes a flexible printed circuit board 510, an adhering layer 520 and the stiffener 20. The flexible printed circuit board 50 has a strengthening surface 511. The adhering layer 520 is adhered to the strengthening surface 511 and is sandwiched between the flexible printed circuit board 510 and the stiffener 20 by a thermal press process, and thus the stiffener 20 is attached on the flexible printed circuit board 50 via the adhering layer 520. The adhering layer 520 is comprised of polyetherimide represented by the following general formula:

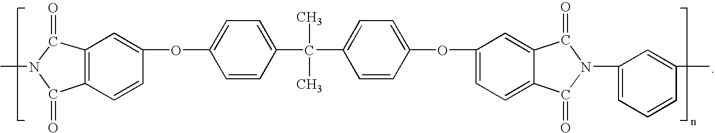

The adhering layer 520 has a thickness in a range from 25 to 70 microns. Thus, the adhering layer 520 will not affect flexibility of the strengthened flexible printed circuit board 50 having the stiffener 20 to be suitable for a roll-to-roll process.

It is noted that the stiffener 30, 40 can be used as a substitute of the stiffener 20 of the strengthened flexible printed circuit board 50 so as to increase mechanical strength of the flexible printed circuit board 610.

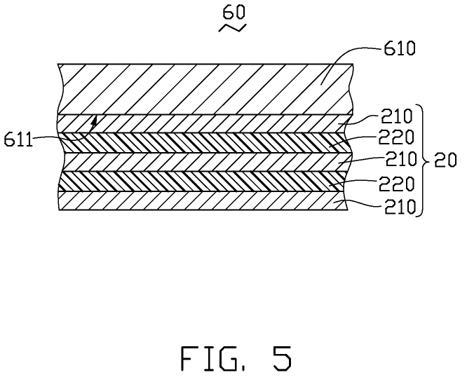

Referring to FIG. 5, another strengthened flexible printed circuit board 60 having the stiffener 20 is shown. The strengthened flexible printed circuit board 610 includes a flexible printed circuit board 610 and the stiffener 20. The flexible printed circuit board 610 has a strengthening surface 611. The polyimide layer 210 on the outer side of the stiffener 20 is directly adhered to the strengthening surface 611 by a thermal press process, and thus the stiffener 20 is attached onto the flexible printed circuit board 610.

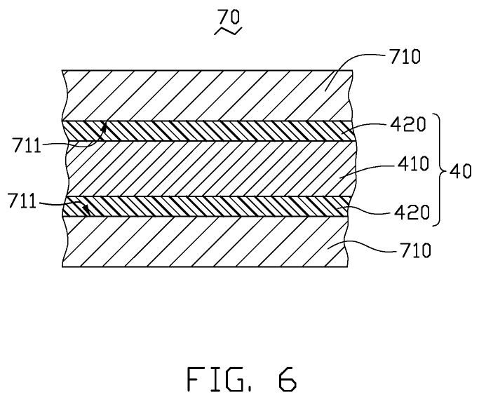

Referring to FIG. 6, a strengthened flexible printed circuit board 70 having the stiffener 40 is shown. The strengthened flexible printed circuit board 70 includes a flexible printed circuit board 710 and the stiffener 40. In the present embodiment, the flexible printed circuit board 710 is bent so as to form two strengthening surfaces 711 facing each other. The stiffener 40 is used to maintain the bent structure of the flexible printed circuit board 710 and strengthen the flexible printed circuit board 710. The two polyetherimide layers 420 on the outer sides of the stiffener 40 are directly adhered to the two strengthening surfaces 711 respectively using a thermal press process, and thus the stiffener 40 is attached onto the flexible printed circuit board 710.

It is noted that one polyetherimide layer 420 on the outer side of the stiffener 40 can adhere to a flexible printed circuit board, another polyetherimide layer 420 on the outer sides of the stiffener 40 can adhere to other component such as a rigid printed circuit board, a support and an electronic component.

It is also note that the stiffener 20, 30, 40 can be used to adhere to other flexible substrates such as a flexible copper and a copper clad laminate to increase mechanical strength of the flexible substrates. Thus, due to the strength of the flexible substrates being increased, processing of the strengthened flexible substrates become easy.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A stiffener, comprising:
at least one polyimide layer and at least one polyetherimide layer adhered to the at least one polyimide layer, the at least one polyetherimide layer being represented by the following general formula:

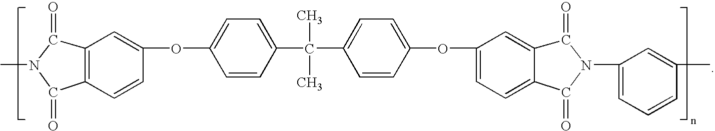

2. The stiffener as claimed in claim 1, wherein a coefficient of thermal expansion of the at least one polyetherimide layer is in a range from 16×10⁻⁶ to 18×10⁻⁶K⁻¹.

3. The stiffener as claimed in claim 1, wherein a thickness of each polyetherimide layer is in a range from 25 to 75 microns.

4. The stiffener as claimed in claim 1, wherein a thickness of each polyimide layer is in a range from 25 to 75 microns.

5. The stiffener as claimed in claim 1, wherein a total thickness of the stiffener is in a range from 25 to 250 microns.

6. The stiffener as claimed in claim 1, wherein the at least one polyimide layer includes a plurality of polyimide layers, and the at least one polyetherimide layer includes a plurality of polyetherimide layers, the polyimide layers and the polyetherimide layers arranged in an alternate fashion.

7. The stiffener as claimed in claim 6, wherein the number of the polyimide layer is one greater than that of the polyetherimide layers.

8. The stiffener as claimed in claim 6, wherein the number the polyimide layers is equal to that of the polyetherimide layers.

9. The stiffener as claimed in claim 6, wherein the number of the polyimide layers is one less than that of the polyetherimide layers.

10. A strengthened flexible printed circuit board, comprising:
a flexible printed circuit board; and
a stiffener attached on the flexible printed circuit board, the stiffener comprising at least one polyimide layer and at least one polyetherimide layer adhered to the at least one polyimide layer, the at least one polyetherimide layer being represented by the following general formula:

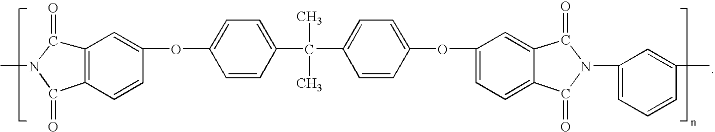

11. The strengthened flexible printed circuit board as claimed in claim 9, wherein a thickness of each polyetherimide layer is in a range from 25 to 75 microns.

12. The strengthened flexible printed circuit board as claimed in claim 9, wherein a thickness of each polyimide layer is in a range from 25 to 75 microns.

13. The strengthened flexible printed circuit board as claimed in claim 9, wherein a total thickness of the stiffener is in a range from 25 to 250 microns.

14. The strengthened flexible printed circuit board as claimed in claim 9, further comprising an adhering layer sandwiched between the flexible printed circuit board and the stiffener.

15. The strengthened flexible printed circuit board as claimed in claim 13, wherein a thickness of the adhering layer is in a range from 25 to 75 microns.

16. The strengthened flexible printed circuit board as claimed in claim 10, wherein the at least one polyimide layer includes a plurality of polyimide layers, and the at least one polyetherimide layer includes a plurality of polyetherimide layers, the polyimide layers and the polyetherimide layers arranged in an alternate fashion.

17. The strengthened flexible printed circuit board as claimed in claim 16, wherein the number of the polyimide layers is one greater than that of the polyetherimide layers.

18. The strengthened flexible printed circuit board as claimed in claim 16, wherein the number of the polyimide layers is equal to that of the polyetherimide layers, and one outside polyetherimide layer is adhered to the flexible printed circuit board.

19. The strengthened flexible printed circuit board as claimed in claim 16, wherein the number of the polyimide layers is equal to that of the polyetherimide layers.

20. A strengthened flexible article comprising:
a flexible substrate; and
a stiffener attached on the flexible substrate, the stiffener comprised a plurality of polyetherimide layers, the polyetherimide layers being represented by a formula: [chemical structure]
